(19) United States
(12) Patent Application Publication
(10) Pub. No.: US 2018/0138202 A1
(43) Pub. Date: May 17, 2018

(54) SEMICONDUCTOR STRUCTURES AND METHOD FOR FABRICATING THE SAME

(71) Applicant: Vanguard International Semiconductor Corporation, Hsinchu (TW)

(72) Inventors: Shih-Kai WU, Hsinchu City (TW); Cheng-Yu WANG, Chiayi City (TW)

(73) Assignee: Vanguard International Semiconductor Corporation, Hsinchu (TW)

(21) Appl. No.: 15/352,151

(22) Filed: Nov. 15, 2016

(51) Int. Cl. H01L 27/12; H01L 23/535; H01L 21/84; H01L 21/768; H01L 21/027; H01L 21/311; H01L 21/308; H01L 21/02; H01L 23/00

(52) U.S. Cl. CPC H01L 27/1203; H01L 23/535; H01L 21/84; H01L 21/76802; H01L 21/76877; H01L 23/562; H01L 21/0273; H01L 21/31144; H01L 21/3081; H01L 21/02164; H01L 21/02194; H01L 21/76831

(57) ABSTRACT

A semiconductor structure is provided, which includes a first substrate, an oxide layer formed on the first substrate, a second substrate formed on the oxide layer, a plurality of semiconductor devices formed in the second substrate, a plurality of first trenches, a contact window, and a third trench. The first trenches are formed in the second substrate and filled with dielectric material and conductive material. The first trenches are separated from each other. One of the first trenches surrounds one of the semiconductor devices. The contact window is formed in the second substrate through the oxide layer and is connected to the first substrate. The contact window is filled with the dielectric material and the conductive material. The third trench is formed in the second substrate and is filled with the dielectric material and the conductive material. The third trench surrounds the contact window.

### BACKGROUND OF THE INVENTION

### Field of the Invention

The invention relates to a semiconductor structure, and more particularly to a semiconductor structure with a top-side contact (TSC) and method for fabricating the same.

### Description of the Related Art

In current semiconductor processes, trenches are usually fabricated in a front end of line (FEOL) process. The FEOL includes various high-temperature processes, for example, each step in forming transistor devices. Therefore, when a single trench with a wide width is fabricated and a single oxide material is filled into it, the result of the thermal expansion and contraction caused by alternating between high and low temperatures is formation of dislocation defects in the structure, particularly at the interface between the trenches and the substrate. This is due to the interaction of internal stresses, which can cause devices to experience problems with current leakage.

In order to effectively control the influence of internal stress in an insulation structure in a silicon-on-insulator (SOI) structure, filling the existing trench pattern areas with a composite material is required to prevent process defects. For a more convenient trench pattern design, the formation of cross intersections in the trench patterns is permitted. However, if the cross intersection areas of the trenches are not filled and flattened, when subsequent metal interconnections cross these intersections, a cross-line short-circuit may be formed. Therefore, the use of thicker composite material and treatment with a chemical mechanical polishing (CMP) process are required in order to completely fill the trenches, resulting in an increase in the cost.

Additionally, in order to comply with the application requirements of some circuit designs, it may be necessary for a buried oxide (BOX) of a silicon-on-insulator (SOI) to be opened. Upper and lower silicon substrates are then connected to form the so-called top-side contact (TSC) and various voltages are applied thereon to change or stabilize the characteristics of devices. However, when various device architectures require an increased thickness of the buried oxide (BOX) in the silicon-on-insulator (SOI) structure, a correspondingly thicker hard mask is required in order to open (etch) the oxide layer. However, in conditions of different demands of thickness (height) of an interlayer dielectric (ILD) structure subsequently disposed with various processes or devices, the amount of polishing that the interlayer dielectric (ILD) structure receives through the chemical mechanical polishing (CMP) process may be increased, which will affect the uniformity of thickness of the interlayer dielectric (ILD) structure.

Therefore, the direction taken by the industry's ongoing efforts is toward the development of a semiconductor structure (and a method for fabricating the same) that is capable of having an appropriate insulation effect; having an interlayer dielectric (ILD) structure with uniform thickness; and maintaining the stability of the devices' electrical properties even under conditions where certain low or high voltage is applied.

### BRIEF SUMMARY OF THE INVENTION

One embodiment of the invention provides a semiconductor structure comprising a first substrate; an oxide layer formed on the first substrate; a second substrate formed on the oxide layer; a plurality of semiconductor devices formed in the second substrate; a plurality of first trenches; a contact window; and a third trench. The first trenches are formed in the second substrate. The first trenches are filled with a dielectric material and a conductive material. The first trenches are separated from each other. One of the first trenches surrounds one of the semiconductor devices. The contact window is formed in the second substrate through the oxide layer. The contact window is connected to the first substrate. The contact window is filled with the dielectric material and the conductive material. The third trench is formed in the second substrate. The third trench is filled with the dielectric material and the conductive material. The third trench surrounds the contact window.

One embodiment of the invention provides a method for fabricating a semiconductor structure comprising providing a silicon-on-insulator (SOI) structure comprising a first silicon substrate, an oxide layer and a second silicon substrate, wherein the oxide layer is formed on the first silicon substrate and the second silicon substrate is formed on the oxide layer; forming a plurality of first trenches, a second trench and a third trench having sidewalls and bottoms in the second silicon substrate, wherein the first trenches are separated from each other and the third trench surrounds the second trench; forming a dielectric material on the second silicon substrate to fill a part of the first trenches, the second trench and the third trench; conformally forming a photoresist layer on the second silicon substrate to fill the first trenches, the second trench and the third trench; light-exposing to the photoresist layer above the second trench; etching the second trench using the unexposed photoresist layer as a mask to make the second trench extend through the oxide layer to connect to the first silicon substrate; and filling a conductive material in the second trench to electrically connect to the first silicon substrate.

In the invention, when a top-side contact (TSC) in a semiconductor structure (for example, a silicon-on-insulator (SOI) structure) is fabricated, in order to take into account the reducing thickness of the hard mask required for etching trenches to maintain uniformity of a subsequently formed interlayer dielectric (ILD) structure and effectively controlling process windows of subsequently related processes, a minimum amount and thickness of the hard mask required for opening (etching) the trenches are utilized. After a dielectric material and a photoresist layer with a certain thickness are deposited, a top-side contact (TSC) area for subsequent etching is defined using a mask, and the photoresist layer in the area is further exposed using a manner of enhanced exposure energy to make the photoresist layer remove. The remaining unexposed photoresist layer area is used as an etching protection layer for etching the top-side contact (TSC). The range of the top-side contact (TSC) defining area is enlarged due to strong exposure. Therefore, outside the top-side contact (TSC) defining area, deposition of at least one additional ring trench surrounding the top-side contact (TSC) is required as insulation protection between the top-side contact (TSC) and the silicon-on-insulator (SOI) substrate. Next, a conductive material is filled in the trenches and the fabrication of the present top-side contact (TSC) is completed.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A is a top view of a semiconductor structure in accordance with one embodiment of the invention;

FIG. 1B is a cross-sectional view of the semiconductor structure along a cross-sectional line A-A′ of FIG. 1A;

FIG. 2A is a top view of a semiconductor structure in accordance with one embodiment of the invention;

FIG. 2B is a cross-sectional view of the semiconductor structure along a cross-sectional line A-A′ of FIG. 2A;

FIG. 3A is a top view of a semiconductor structure in accordance with one embodiment of the invention;

FIG. 3B is a cross-sectional view of the semiconductor structure along a cross-sectional line A-A′ of FIG. 3A; and

FIGS. 4A-4D are cross-sectional views of a method for fabricating a semiconductor structure in accordance with one embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

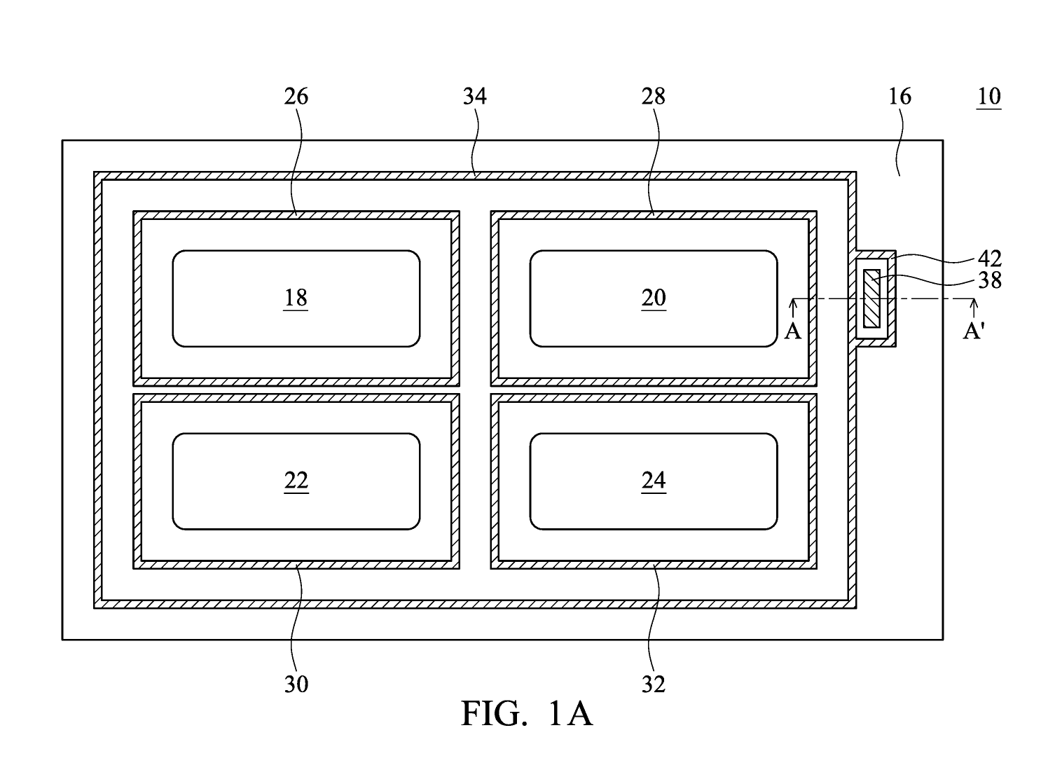

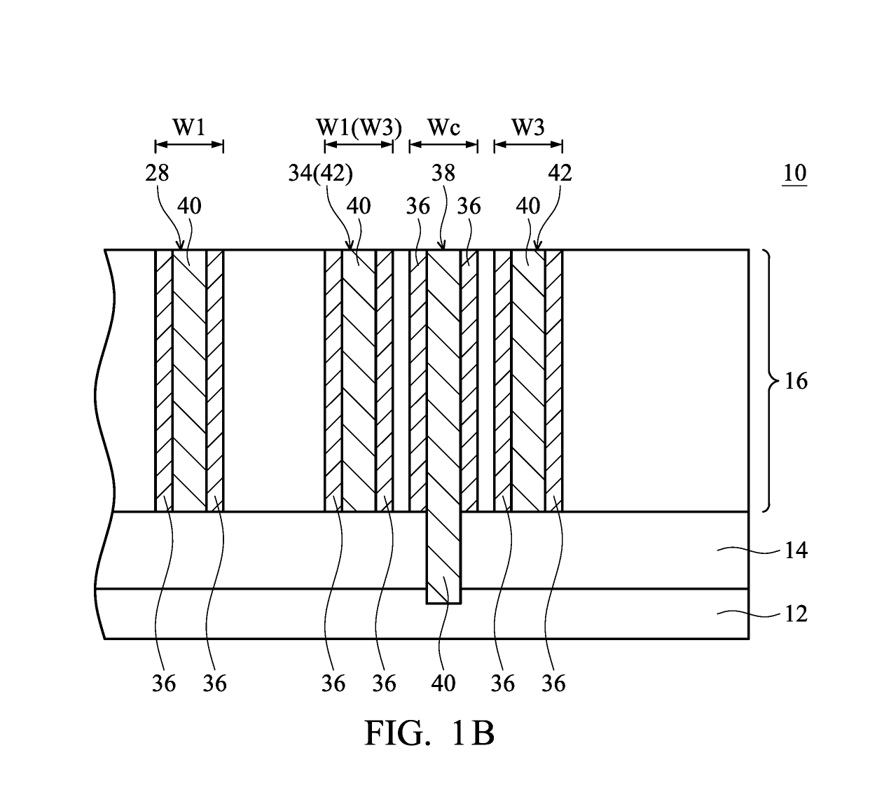

Referring to FIGS. 1A and 1B, in accordance with one embodiment of the invention, a semiconductor structure 10 is provided. FIG. 1A is a top view of the semiconductor structure 10. FIG. 1B is a cross-sectional view of the semiconductor structure 10 along a cross-sectional line A-A′ of FIG. 1A.

As shown in FIGS. 1A and 1B, in this embodiment, the semiconductor structure 10 comprises a first substrate 12, an oxide layer 14, a second substrate 16, a plurality of semiconductor devices (18, 20, 22 and 24), a plurality of first trenches (26, 28, 30, 32 and 34), a contact window 38, and a third trench 42. The oxide layer 14 is formed on the first substrate 12. The second substrate 16 is formed on the oxide layer 14. The semiconductor devices (18, 20, 22 and 24) are formed in the second substrate 16. The first trenches (26, 28, 30, 32 and 34) are formed in the second substrate 16 and filled with a dielectric material 36 and a conductive material 40. Specifically, the first trenches (26, 28, 30, 32 and 34) are separated from each other and one of the first trenches (26, 28, 30 and 32) surrounds one of the semiconductor devices (18, 20, 22 and 24). That is, each of the semiconductor devices is surrounded by one trench. For example, the first trench 26 surrounds the semiconductor device 18, the first trench 28 surrounds the semiconductor device 20, the first trench 30 surrounds the semiconductor device 22, and the first trench 32 surrounds the semiconductor device 24, as shown in FIG. 1A.

Additionally, the contact window 38 is formed in the second substrate 16 and extended through the oxide layer 14 to connect to the first substrate 12. The contact window 38 is filled with the dielectric material 36 and the conductive material 40.

Furthermore, the third trench 42 is formed in the second substrate 16 and filled with the insulation material 36 and the conductive material 40. Specifically, the third trench 42 surrounds the contact window 38.

In some embodiments, the first substrate 12 and the second substrate 16 may be silicon substrates such that the semiconductor structure 10 is formed into a silicon-on-insulator (SOI) structure.

In some embodiments, the oxide layer 14 has thickness of about 0.5-3 μm.

In some embodiments, the semiconductor devices (18, 20, 22 and 24) may comprise various high-voltage or low-voltage devices, including, but not limited to, field-effect transistors (FETs) or bipolar junction transistors (BJTs).

In some embodiments, the first trenches (26, 28, 30, 32 and 34) have widths W1 which are the same as the width Wc of the contact window 38 and the width W3 of the third trench 42.

In some embodiments, the width W1 of the first trenches (26, 28, 30, 32 and 34), the width Wc of the contact window 38 and the width W3 of the third trench 42 are about 0.5-2 μm.

In some embodiments, the dielectric material 36 may comprise various suitable dielectric materials, for example, barium strontium titanate (BST) or silicon dioxide.

In some embodiments, the conductive material 40 may comprise various suitable metal materials.

In this embodiment, the contact window 38 is a top-side contact (TSC).

In this embodiment, the first trenches (26, 28, 30, 32 and 34) partially overlap the third trench 42. For example, the first trench 34 overlaps one side of the third trench 42, as shown in FIG. 1A.

In this embodiment, when a specific low voltage is applied to the contact window 38, a semiconductor device zone (i.e. the zone including the semiconductor devices (18, 20, 22 and 24)) acquires sufficient insulation protection through disposition of the first trenches (26, 28, 30, 32 and 34) and the third trench 42.

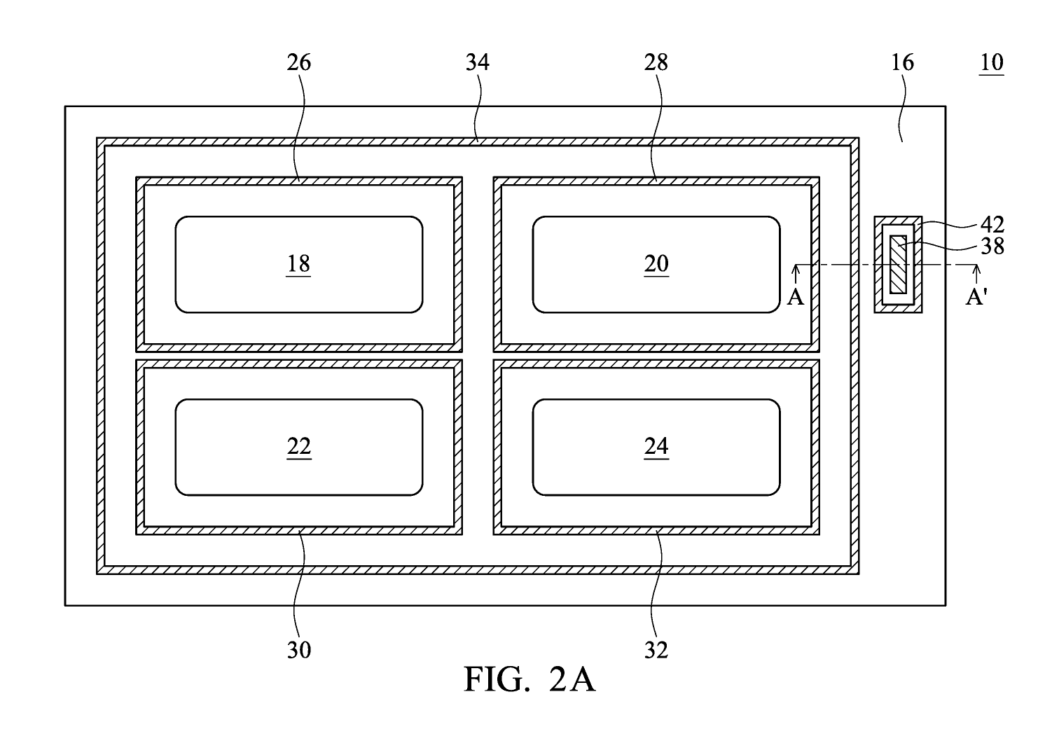

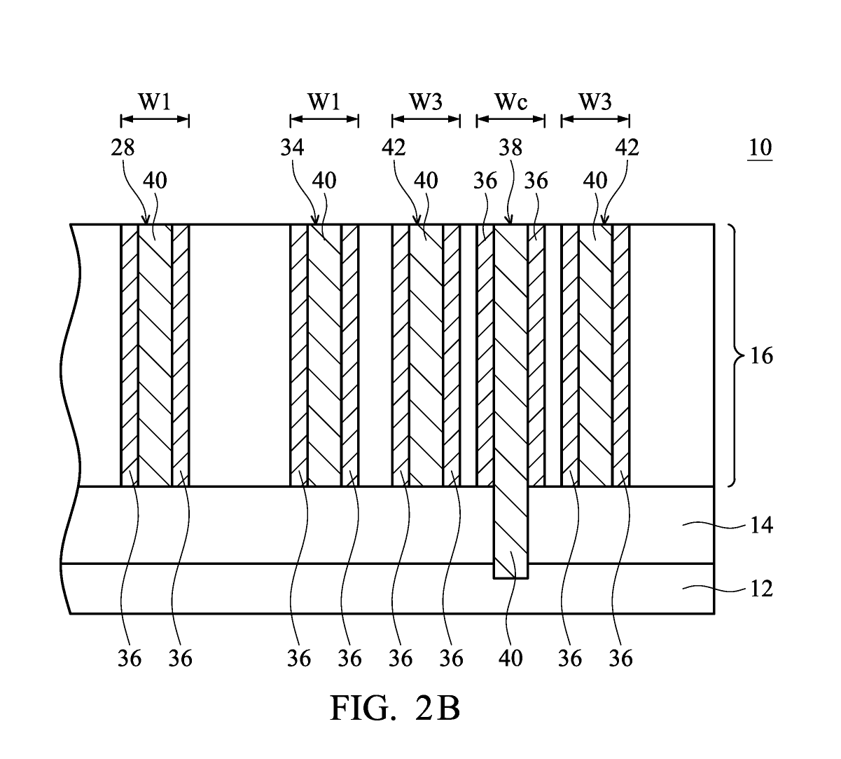

Referring to FIGS. 2A and 2B, in accordance with one embodiment of the invention, a semiconductor structure 10 is provided. FIG. 2A is a top view of the semiconductor structure 10. FIG. 2B is a cross-sectional view of the semiconductor structure 10 along a cross-sectional line A-A′ of FIG. 2A.

As shown in FIGS. 2A and 2B, in this embodiment, the semiconductor structure 10 comprises a first substrate 12, an oxide layer 14, a second substrate 16, a plurality of semiconductor devices (18, 20, 22 and 24), a plurality of first trenches (26, 28, 30, 32 and 34), a contact window 38, and a third trench 42. The oxide layer 14 is formed on the first substrate 12. The second substrate 16 is formed on the oxide layer 14. The semiconductor devices (18, 20, 22 and 24) are formed in the second substrate 16. The first trenches (26, 28, 30, 32 and 34) are formed in the second substrate 16 and filled with a dielectric material 36 and a conductive material 40. Specifically, the first trenches (26, 28, 30, 32 and 34) are separated from each other and one of the first trenches (26, 28, 30 and 32) surrounds one of the semiconductor devices (18, 20, 22 and 24). That is, each of the semiconductor devices is surrounded by one trench. For example, the first trench 26 surrounds the semiconductor device 18, the first trench 28 surrounds the semiconductor device 20, the first trench 30 surrounds the semiconductor device 22, and the first trench 32 surrounds the semiconductor device 24, as shown in FIG. 2A.

Additionally, the contact window 38 is formed in the second substrate 16 and extended through the oxide layer 14 to connect to the first substrate 12. The contact window 38 is filled with the dielectric material 36 and the conductive material 40.

Furthermore, the third trench 42 is formed in the second substrate 16 and filled with the dielectric material 36 and the conductive material 40. Specifically, the third trench 42 surrounds the contact window 38.

In some embodiments, the first substrate 12 and the second substrate 16 may be silicon substrates such that the semiconductor structure 10 is formed into a silicon-on-insulator (SOI) structure.

In some embodiments, the oxide layer 14 has thickness of about 0.5-3 μm.

In some embodiments, the semiconductor devices (18, 20, 22 and 24) may comprise various high-voltage or low-voltage devices, including, but not limited to, field-effect transistors (FETs) or bipolar junction transistors (BJTs).

In some embodiments, the first trenches (26, 28, 30, 32 and 34) have widths W1 which are the same as the width Wc of the contact window 38 and the width W3 of the third trench 42.

In some embodiments, the width W1 of the first trenches (26, 28, 30, 32 and 34), the width Wc of the contact window 38 and the width W3 of the third trench 42 are about 1-2 μm.

In some embodiments, the dielectric material 36 may comprise various suitable dielectric materials, for example, barium strontium titanate (BST) or silicon dioxide.

In some embodiments, the conductive material 40 may comprise various suitable metal materials.

In this embodiment, the contact window 38 is a top-side contact (TSC).

In this embodiment, the first trenches (26, 28, 30, 32 and 34) are separated from the third trench 42. For example, the first trench 34 does not overlap any one side of the third trench 42, as shown in FIG. 2A.

In this embodiment, when a specific high voltage is applied to the contact window 38, a semiconductor device zone (i.e. the zone including the semiconductor devices (18, 20, 22 and 24)) acquires sufficient insulation protection through disposition of the first trenches (26, 28, 30, 32 and 34) and the third trench 42.

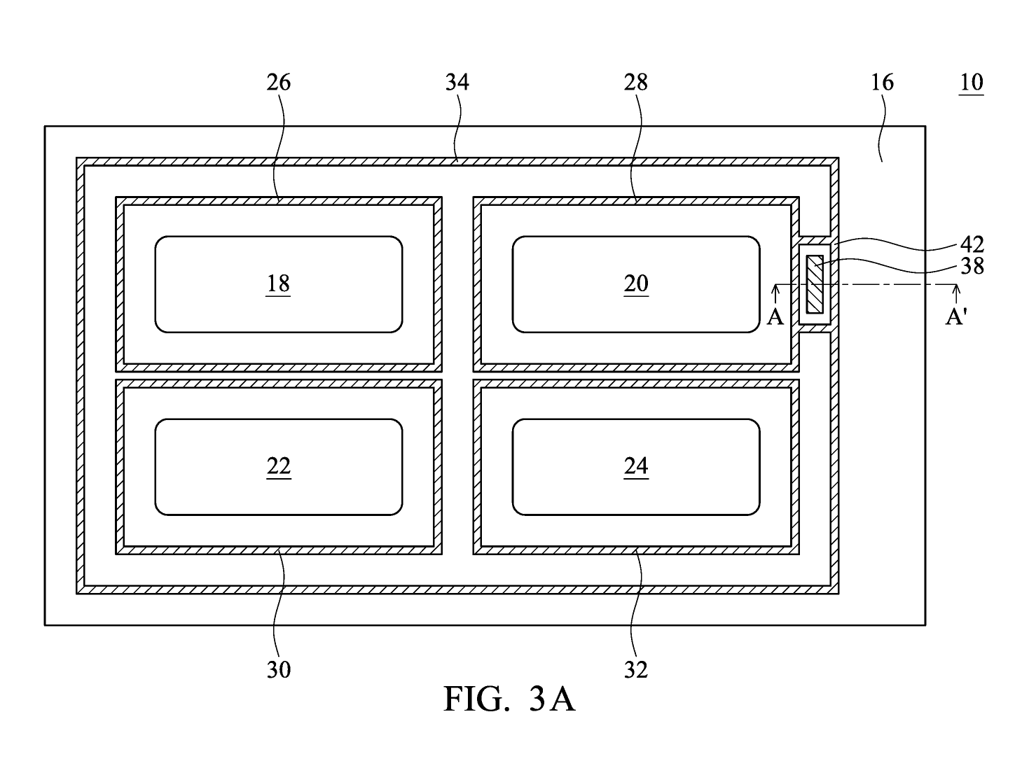

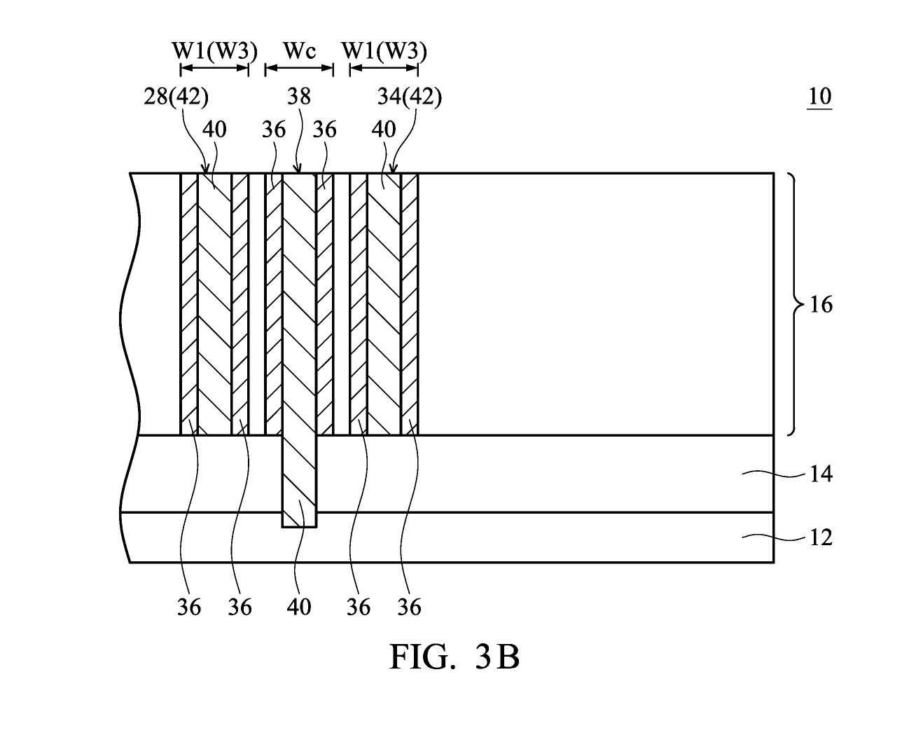

Referring to FIGS. 3A and 3B, in accordance with one embodiment of the invention, a semiconductor structure 10 is provided. FIG. 3A is a top view of the semiconductor structure 10. FIG. 3B is a cross-sectional view of the semiconductor structure 10 along a cross-sectional line A-A′ of FIG. 3A.

As shown in FIGS. 3A and 3B, in this embodiment, the semiconductor structure 10 comprises a first substrate 12, an oxide layer 14, a second substrate 16, a plurality of semiconductor devices (18, 20, 22 and 24), a plurality of first trenches (26, 28, 30, 32 and 34), a contact window 38, and a third trench 42. The oxide layer 14 is formed on the first substrate 12. The second substrate 16 is formed on the oxide layer 14. The semiconductor devices (18, 20, 22 and 24) are formed in the second substrate 16. The first trenches (26, 28, 30, 32 and 34) are formed in the second substrate 16 and filled with a dielectric material 36 and a conductive material 40. Specifically, the first trenches (26, 28, 30, 32 and 34) are separated from each other and one of the first trenches (26, 28, 30 and 32) surrounds one of the semiconductor devices (18, 20, 22 and 24). That is, each of the semiconductor devices is surrounded by one trench. For example, the first trench 26 surrounds the semiconductor device 18, the first trench 28 surrounds the semiconductor device 20, the first trench 30 surrounds the semiconductor device 22, and the first trench 32 surrounds the semiconductor device 24, as shown in FIG. 3A.

Additionally, the contact window 38 is formed in the second substrate 16 and extended through the oxide layer 14 to connect to the first substrate 12. The contact window 38 is filled with the dielectric material 36 and the conductive material 40.

Furthermore, the third trench 42 is formed in the second substrate 16 and filled with the dielectric material 36 and the conductive material 40. Specifically, the third trench 42 surrounds the contact window 38.

In some embodiments, the first substrate 12 and the second substrate 16 may be silicon substrates such that the semiconductor structure 10 is formed into a silicon-on-insulator (SOI) structure.

In some embodiments, the oxide layer 14 has thickness of about 0.5-3 μm.

In some embodiments, the semiconductor devices (18, 20, 22 and 24) may comprise various high-voltage or low-voltage devices, including, but not limited to, field-effect transistors (FETs) or bipolar junction transistors (BJTs).

In some embodiments, the first trenches (26, 28, 30, 32 and 34) have widths W1 which are the same as the width Wc of the contact window 38 and the width W3 of the third trench 42.

In some embodiments, the width W1 of the first trenches (26, 28, 30, 32 and 34), the width Wc of the contact window 38 and the width W3 of the third trench 42 are about 1-2 μm.

In some embodiments, the dielectric material 36 may comprise various suitable dielectric materials, for example, barium strontium titanate (BST) or silicon dioxide.

In some embodiments, the conductive material 40 may comprise various suitable metal materials.

In this embodiment, the contact window 38 is a top-side contact (TSC).

In this embodiment, the first trenches (26, 28, 30, 32 and 34) partially overlap the third trench 42. For example, the first trenches (28 and 34) overlap two sides of the third trench 42, as shown in FIG. 3A.

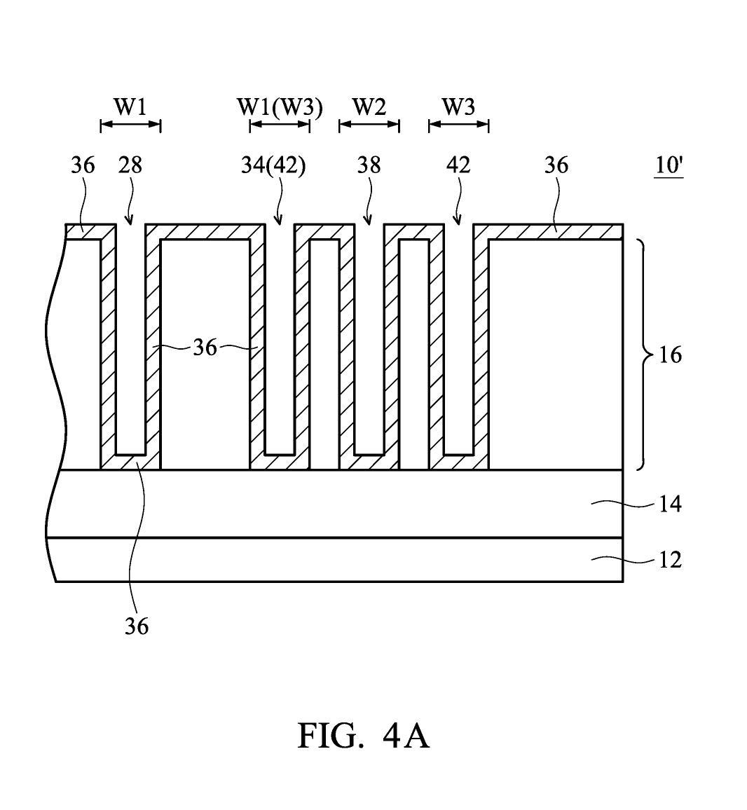

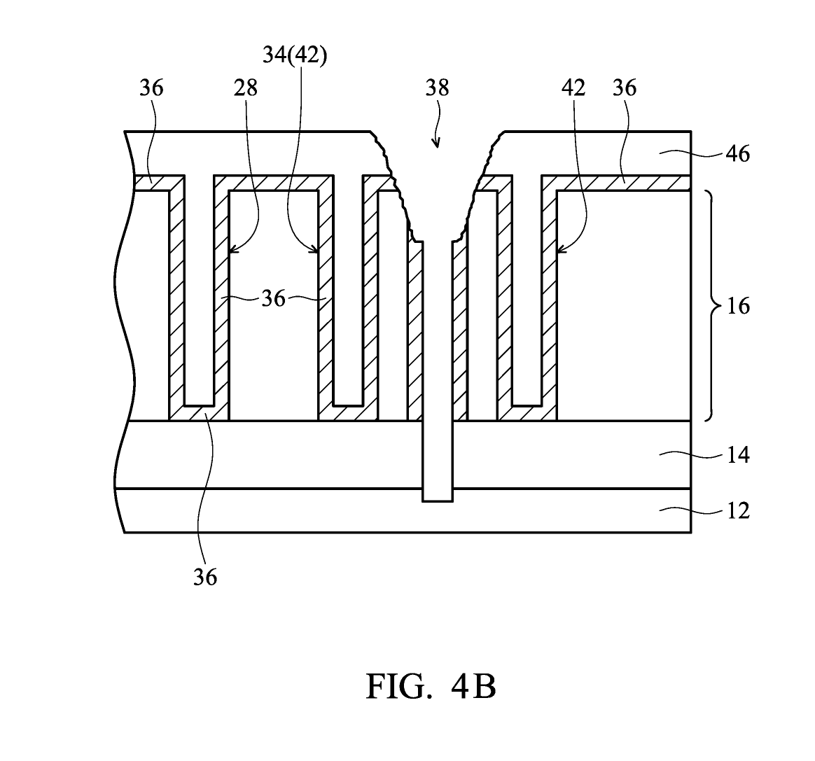

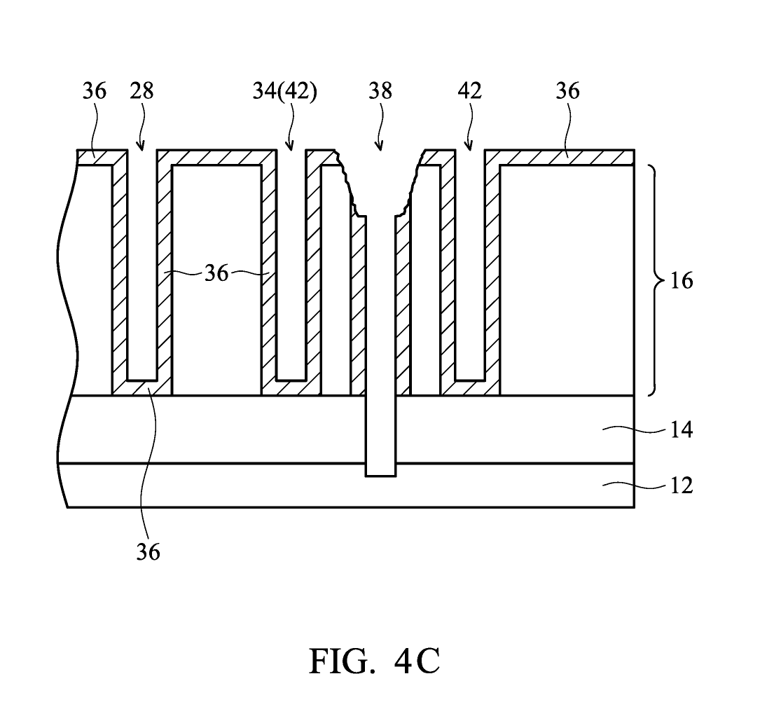

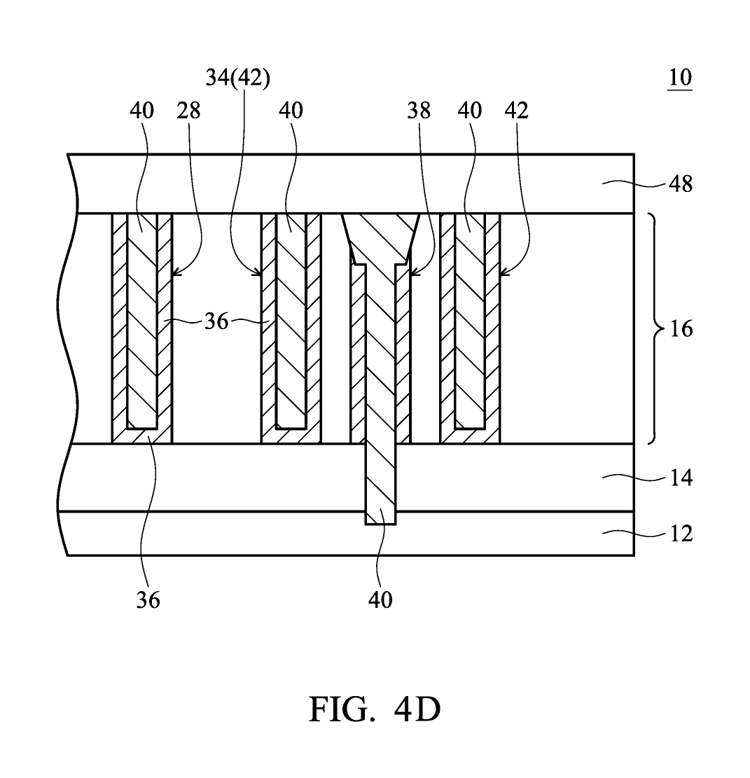

Referring to FIGS. 1A-1B and 4A-4D, in accordance with one embodiment of the invention, a method for fabricating the semiconductor structure 10 (as shown in FIGS. 1A and 1B) is provided. FIGS. 4A-4D are cross-sectional views of the method for fabricating the semiconductor structure 10.

Referring to FIG. 4A, a silicon-on-insulator (SOI) structure 10′ is provided.

As shown in FIG. 4A, the silicon-on-insulator (SOI) structure 10′ comprises a first silicon substrate 12, an oxide layer 14 and a second silicon substrate 16. The oxide layer 14 is formed on the first silicon substrate 12. The second silicon substrate 16 is formed on the oxide layer 14.

In some embodiments, the oxide layer 14 has thickness of about 0.5-3 μm.

A patterned hard mask film (not shown) is formed on the second silicon substrate 16.

In some embodiments, the patterned hard mask film is formed on the second silicon substrate 16 by, for example, chemical vapor deposition (CVD) or physical vapor deposition (PVD) and a patterning process.

In some embodiments, the patterned hard mask film may comprise, but not limited to, silicon oxide (SiO), silicon nitride (SiN), silicon carbide (SiC), silicon oxide nitride (SiON), silicon carbide nitride (SiCN), silicon oxide carbide nitride (SiOCN), tantalum (Ta), tantalum nitride (TaN), titanium (Ti), titanium nitride (TiN), aluminum oxide (Al₂O₃), boron nitride (BN), hydrogen silsesquioxane (HSQ) or another suitable material with high etch selectivity.

The second silicon substrate 16 is etched through the patterned hard mask film to form a plurality of first trenches (26, 28, 30, 32 and 34), a second trench 38 and a third trench 42 in the second silicon substrate 16. Specifically, the first trenches (26, 28, 30, 32 and 34) are separated from each other and the third trench 42 surrounds the second trench 38.

In some embodiments, the first trenches (26, 28, 30, 32 and 34) have widths W1 which are about the same as the width W2 of the second trench 38 and the width W3 of the third trench 42.

In some embodiments, the width W1 of the first trenches (26, 28, 30, 32 and 34), the width W2 of the second trench 38 and the width W3 of the third trench 42 are about 1-2 μm.

In this embodiment, the first trenches (26, 28, 30, 32 and 34) partially overlap the third trench 42. For example, the first trench 34 overlaps one side of the third trench 42, as shown in FIG. 1A.

In other embodiments, the first trenches (26, 28, 30, 32 and 34) may be separated from the third trench 42. For example, the first trench 34 does not overlap any one side of the third trench 42, as shown in FIG. 2A.

A dielectric material 36 is formed on the second silicon substrate 16 to fill a part of the first trenches (26, 28, 30, 32 and 34), the second trench 38 and the third trench 42, for example, filling the sidewalls and bottoms of the first trenches (26, 28, 30, 32 and 34), the second trench 38 and the third trench 42.

In some embodiments, the dielectric material 36 is formed on the second silicon substrate 16 to fill the part of the first trenches (26, 28, 30, 32 and 34), the second trench 38 and the third trench 42 by, for example, chemical vapor deposition (CVD) or physical vapor deposition (PVD).

In some embodiments, the dielectric material 36 may comprise various suitable dielectric materials, for example, barium strontium titanate (BST) or silicon dioxide.

Referring to FIG. 4B, a photoresist layer 46 is conformally formed on the second silicon substrate 16 to fill the first trenches (26, 28, 30, 32 and 34), the second trench 38 and the third trench 42.

The photoresist layer 46 above the second trench 38 is exposed to remove the photoresist layer 46 in the second trench 38.

The second trench 38 is etched using the unexposed photoresist layer 46 as a mask to make the second trench 38 extend through the oxide layer 14 to connect to the first silicon substrate 12.

In some embodiments, the oxide layer 14 and the photoresist layer 46 have a ratio of thickness from 1:2 to 1:5.

Referring to FIG. 4C, the photoresist layer 46 above the second silicon substrate 16 and the photoresist layer 46 in the first trenches (26, 28, 30, 32 and 34) and the third trench 42 are removed.

Referring to FIG. 4D, a conductive material 40 is filled in the second trench 38 to form a contact window 38 to electrically connect to the first silicon substrate 12.

In some embodiments, the conductive material 40 is filled in the second trench 38 by, for example, chemical vapor deposition (CVD) or physical vapor deposition (PVD) and an etch-back process.

In some embodiments, the conductive material 40 may comprise various suitable metal materials.

In this embodiment, the contact window 38 is a top-side contact (TSC).

In this embodiment, the conductive material 40 is further filled in the first trenches (26, 28, 30, 32 and 34) and the third trench 42.

In this embodiment, an interlayer dielectric (ILD) 48 is further formed on the second silicon substrate 16.

From this, the fabrication of the semiconductor structure 10 (as shown in FIGS. 1A and 1B) is completed.

In the invention, when a top-side contact (TSC) in a semiconductor structure (for example, a silicon-on-insulator (SOI) structure) is fabricated, in order to take into account the reducing thickness of the hard mask required for etching trenches to maintain uniformity of a subsequently formed interlayer dielectric (ILD) structure and effectively controlling process windows of subsequently related processes, a minimum amount and thickness of the hard mask required for opening (etching) the trenches are utilized. After a dielectric material and a photoresist layer with a certain thickness are deposited, a top-side contact (TSC) area for subsequent etching is defined using a mask, and the photoresist layer in the area is further exposed using a manner of enhanced exposure energy to make the photoresist layer remove. The remaining unexposed photoresist layer area is used as an etching protection layer for etching the top-side contact (TSC). The range of the top-side contact (TSC) defining area is enlarged due to strong exposure. Therefore, outside the top-side contact (TSC) defining area, deposition of at least one additional ring trench surrounding the top-side contact (TSC) is required as insulation protection between the top-side contact (TSC) and the silicon-on-insulator (SOI) substrate. Next, a conductive material is filled in the trenches and the fabrication of the present top-side contact (TSC) is completed.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a first substrate;
an oxide layer formed on the first substrate;
a second substrate formed on the oxide layer;
a plurality of semiconductor devices formed in the second substrate;
a plurality of first trenches formed in the second substrate and filled with a dielectric material and a conductive material, wherein the first trenches are separated from each other and one of the first trenches surrounds one of the semiconductor devices;
a contact window formed in the second substrate through the oxide layer and connected to the first substrate, wherein the contact window is filled with the dielectric material and the conductive material; and
a third trench formed in the second substrate and filled with the dielectric material and the conductive material, wherein the third trench surrounds the contact window.

2. The semiconductor structure as claimed in claim 1, wherein the first substrate and the second substrate are silicon substrates.

3. The semiconductor structure as claimed in claim 1, wherein the oxide layer has thickness of 0.5-3 μm.

4. The semiconductor structure as claimed in claim 1, wherein the semiconductor device comprises field-effect transistors (FETs) or bipolar junction transistors (BJTs).

5. The semiconductor structure as claimed in claim 1, wherein the first trenches have a width that is the same as those of the contact window and the third trench.

6. The semiconductor structure as claimed in claim 1, wherein the first trenches, the contact window and the third trench have widths of 1-2 μm.

7. The semiconductor structure as claimed in claim 1, wherein the first trenches are separated from the third trench.

8. The semiconductor structure as claimed in claim 1, wherein the first trenches partially overlap the third trench.

9. The semiconductor structure as claimed in claim 1, wherein the dielectric material comprises barium strontium titanate (BST) or silicon dioxide.

10. A method for fabricating a semiconductor structure, comprising:
providing a silicon-on-insulator (SOI) structure comprising a first silicon substrate, an oxide layer and a second silicon substrate, wherein the oxide layer is formed on the first silicon substrate and the second silicon substrate is formed on the oxide layer;
forming a plurality of first trenches, a second trench and a third trench having sidewalls and bottoms in the second silicon substrate, wherein the first trenches are separated from each other and the third trench surrounds the second trench;
forming a dielectric material on the second silicon substrate to fill a part of the first trenches, the second trench and the third trench;
conformally forming a photoresist layer on the second silicon substrate to fill the first trenches, the second trench and the third trench;
exposing to the photoresist layer above the second trench;
etching the second trench using the unexposed photoresist layer as a mask to make the second trench extend through the oxide layer to connect to the first silicon substrate; and
filling a conductive material in the second trench to electrically connect to the first silicon substrate.

11. The method for fabricating a semiconductor structure as claimed in claim 10, wherein the oxide layer has thickness of 0.5-3 μm.

12. The method for fabricating a semiconductor structure as claimed in claim 10, wherein the first trenches have a width that is the same as those of the second trench and the third trench.

13. The method for fabricating a semiconductor structure as claimed in claim 10, wherein the first trenches, the second trench and the third trench have widths of 1-2 μm.

14. The method for fabricating a semiconductor structure as claimed in claim 10, wherein the first trenches are separated from the third trench.

15. The method for fabricating a semiconductor structure as claimed in claim 10, wherein the first trenches partially overlap the third trench.

16. The method for fabricating a semiconductor structure as claimed in claim 10, wherein the dielectric material is filled and on the sidewalls and the bottoms of the first trenches, the second trench and the third trench.

17. The method for fabricating a semiconductor structure as claimed in claim 10, wherein the dielectric material comprises barium strontium titanate (BST) or silicon dioxide.

18. The method for fabricating a semiconductor structure as claimed in claim 10, wherein the oxide layer and the photoresist layer have a ratio of thickness from 1:2 to 1:5.

19. The method for fabricating a semiconductor structure as claimed in claim 10, further comprising filling the conductive material in the first trenches and the third trench.

20. The method for fabricating a semiconductor structure as claimed in claim 10, further comprising forming an interlayer dielectric (ILD) on the second silicon substrate.
